(19) United States
(12) Patent Application Publication
(10) Pub. No.: US 2026/0081581 A1
(43) Pub. Date: Mar. 19, 2026

(54) LAMB WAVE RESONATOR HAVING PIEZOELECTRIC LAYER WITH ENGINEERED REGION

(71) Applicant: Skyworks Global Pte. Ltd., Singapore (SG)

(72) Inventors: Kwang Jae Shin, Yongin-si (KR); Stefan Bader, Fort Collins, CO (US); Zongliang Cao, Irvine, CA (US); Yanbo He, Irvine, CA (US)

(21) Appl. No.: 19/317,955

(22) Filed: Sep. 3, 2025

Related U.S. Application Data
(60) Provisional application No. 63/695,245, filed on Sep. 16, 2024.

(51) Int. Cl. H03H 9/15; H03H 9/02; H03H 9/56

(52) U.S. Cl. CPC H03H 9/15; H03H 9/02228; H03H 9/568

(57) ABSTRACT

Aspects of this disclosure relate to a Lamb wave resonator with a piezoelectric layer that is less piezoelectric in a border region than in an active region. End portions of interdigital transducer electrode fingers of the Lamb wave resonator are in the border region. Related filters, multiplexers, radio frequency modules, radio frequency systems, wireless communication devices, and methods are also disclosed.

### CROSS REFERENCE TO PRIORITY APPLICATION

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/695,245, filed Sep. 16, 2024 and titled “LAMB WAVE RESONATOR HAVING PIEZOELECTRIC LAYER WITH ENGINEERED REGION,” the disclosure of which is hereby incorporated by reference in its entirety and for all purposes.

### BACKGROUND

### Technical Field

The disclosed technology relates to acoustic wave devices. Embodiments of this disclosure relate to Lamb wave resonators having a piezoelectric layer with an engineered region.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include Lamb wave resonators.

For acoustic wave devices, achieving a high quality factor (Q) and suppressing transverse modes can be desirable. There are technical challenges related to increasing Q and suppressing transverse modes.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a Lamb wave resonator having an active region and a border region. The Lamb wave resonator includes a piezoelectric layer and an interdigital transducer electrode. The piezoelectric layer has an effective piezoelectric coefficient in the border region with a lower magnitude than an effective piezoelectric coefficient in the active region. The interdigital transducer electrode includes a plurality of interdigital transducer electrode fingers having respective end portions in the border region. The Lamb wave resonator is configured to generate a Lamb wave.

The Lamb wave resonator can include an electrode on an opposite side of the piezoelectric layer than the interdigital transducer electrode. The Lamb wave resonator can include a seed layer positioned between the electrode and the piezoelectric layer in at least the border region. The Lamb wave resonator can be free from the seed layer in the active region. The Lamb wave resonator can include an air cavity, where the electrode is positioned between at least a portion of the piezoelectric layer and the air cavity.

The interdigital transducer electrode can include a piston mode structure in the border region. The end portions of the interdigital transducer electrode can be hammer head shaped in plan view.

The Lamb wave resonator can have a gap region and a bus bar region, where the gap region is between the border region and the bus bar region. The piezoelectric layer can have an effective piezoelectric coefficient in the gap region with a lower magnitude than the effective piezoelectric coefficient in the active region. The piezoelectric layer can have an effective piezoelectric coefficient in the bus bar region with a lower magnitude than the effective piezoelectric coefficient in the active region.

The Lamb wave resonator can be configured to operate in a lowest order symmetric (S₀) mode. The Lamb wave resonator can be configured to operate in a first order symmetric (S₁) mode.

The Lamb wave resonator can have free edges.

The piezoelectric layer can include aluminum nitride. The piezoelectric layer can include an aluminum nitride layer doped with scandium.

The effective piezoelectric coefficient of the piezoelectric layer in the border region can have a magnitude that is less than 50% of a magnitude of the effective piezoelectric coefficient of the piezoelectric layer in the active region.

Another aspect of this disclosure is a Lamb wave resonator that includes an interdigital transducer electrode and a piezoelectric layer. The interdigital transducer electrode includes a plurality of interdigital transducer electrode fingers having respective end portions. The piezoelectric layer has an active region and an engineered region. The engineered region overlaps with the end portions of the interdigital transducer electrode fingers. The Lamb wave resonator is configured to generate a Lamb wave.

The Lamb wave resonator can include an electrode on an opposite side of the piezoelectric layer than the interdigital transducer electrode. The Lamb wave resonator can include a seed layer positioned between the electrode and the engineered region of the piezoelectric layer. The Lamb wave resonator can be free from the seed layer between the electrode and the active region of the piezoelectric layer. The Lamb wave resonator can include an air cavity, where the electrode is positioned between at least a portion of the piezoelectric layer and the air cavity.

The interdigital transducer electrode can include a piston mode structure that overlaps with the engineered region of the piezoelectric layer. The end portions of the interdigital transducer electrode can be hammer head shaped in plan view.

The engineered region can extend beyond the end portions in a direction away from the active region.

The Lamb wave resonator can be configured to operate in a lowest order symmetric (S₀) mode. The Lamb wave resonator can be configured to operate in a first order symmetric (S₁) mode.

The Lamb wave resonator can have free edges.

The piezoelectric layer can include aluminum nitride. The piezoelectric layer can include an aluminum nitride layer doped with scandium.

An effective piezoelectric coefficient of the piezoelectric layer in the engineered region can have a magnitude that is less than 50% of a magnitude of the effective piezoelectric coefficient of the piezoelectric layer in the active region.

Another aspect of this disclosure is an acoustic wave filter for filtering a radio frequency signal. The acoustic wave filter includes a Lamb wave resonator in accordance with any suitable principles and advantages disclosed herein and a plurality of additional acoustic wave resonators. The Lamb wave resonator and the plurality of additional acoustic wave resonators are configured to filter the radio frequency signal.

Another aspect of this disclosure is a multiplexer for filtering radio frequency signals. The multiplexer includes a first filter including a Lamb wave resonator in accordance with any suitable principles and advantages disclosed herein, and a second filter coupled to the first filter at a common node.

Another aspect of this disclosure is a radio frequency module that includes a filter including a Lamb wave resonator in accordance with any suitable principles and advantages disclosed herein, radio frequency circuitry, and a package structure enclosing the filter and the radio frequency circuitry.

Another aspect of this disclosure is a radio frequency system that includes an antenna, a filter including a Lamb wave resonator in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes a Lamb wave resonator in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal via at least an antenna; and filtering the radio frequency signal with a filter that includes a Lamb wave resonator in accordance with any suitable principles and advantages disclosed herein.

### BRIEF DESCRIPTION OF THE DRAWINGS

Embodiments of this disclosure will now be described, by way of non-limiting example, with reference to the accompanying drawings.

FIG. 1 is a schematic view of an interdigital transducer (IDT) electrode and a related velocity profile.

FIGS. 2A, 2B, 2C, 2D, and 2E are schematic cross-sectional diagrams of piezoelectric layers with engineered regions according to embodiments.

FIG. 3 is a cross-sectional side view of a Lamb wave resonator according to an embodiment.

FIGS. 4A to 4F are diagrams of cross sections of Lamb wave resonators with free edges according to embodiments.

FIGS. 5A to 5F are diagrams of cross sections of Lamb wave resonators with gratings according to embodiments.

FIGS. 6A to 6J are diagrams of IDT electrodes of Lamb wave resonators with piston mode structures according to various embodiments.

FIG. 7 is a schematic block diagram of a semiconductor die that includes a Lamb wave resonator according to an embodiment and complementary metal oxide semiconductor circuitry.

FIG. 8 is a schematic block diagram of an oscillator that includes a Lamb wave resonator according to an embodiment.

FIG. 9 is a schematic block diagram of a sensor that includes a Lamb wave resonator according to an embodiment.

FIG. 10A is a schematic diagram of a ladder filter that includes one or more Lamb wave resonators according to an embodiment. FIG. 10B is schematic diagram of a band pass filter.

FIGS. 11A, 11B, 11C, and 11D are schematic diagrams of multiplexers that include a filter with one or more Lamb wave resonators according to an embodiment.

FIGS. 12, 13, and 14 are schematic block diagrams of modules that include a filter with one or more Lamb wave resonators according to an embodiment.

FIG. 15 is a schematic block diagram of a wireless communication device that includes a filter with one or more Lamb wave resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other. The headings provided herein are for convenience only and are not intended to affect the meaning or scope of the claims.

Acoustic wave filters can filter radio frequency (RF) signals in a variety of applications, such as in an RF front end of a mobile phone. An acoustic wave filter can include acoustic wave resonator resonators. A Lamb wave resonator is an example of an acoustic wave resonator.

A Lamb wave resonator can combine features of a surface acoustic wave (SAW) resonator and a bulk acoustic wave (BAW) resonator. A Lamb wave resonator typically includes an interdigital transducer (IDT) electrode similar to a SAW resonator. The frequency of the Lamb wave resonator can be at least partly lithographically defined. A Lamb wave resonator can achieve a relatively high quality factor (Q) and a relatively high phase velocity like a BAW filter (e.g., due to a suspended structure). A Lamb wave resonator that includes an aluminum nitride piezoelectric layer can be relatively easy to integrate with other circuits, for example, because aluminum nitride (AlN) process technology can be compatible with complementary metal oxide semiconductor (CMOS) process technology. Lamb wave resonators with an AlN piezoelectric layer can overcome technical challenges related to resonance frequency associated with SAW resonators and also overcome multiple frequency capability challenges associated with BAW resonators. AlN Lamb wave resonators can also be desirable due to their relatively small size. A lowest order symmetric (S₀) and a first order symmetric (S₁) modes of AlN Lamb wave resonators can achieve desirable transduction efficiency.

High transducing efficiency modes, such as in S₀ mode and in S₁ mode, in a Lamb wave resonator with type-1 dispersion can create relatively strong multi-transverse modes above resonance frequency concurrently. Apodization of an IDT electrode aperture, higher velocity of an IDT electrode gap, and lower velocity of a border region can be used for transverse spurious mode suppression as well as boosting Q. Lower velocity of the border region can be achieved using a piston mode structure. Piston mode structure can suppress transverse spurious modes. However, transverse spurious modes can still be present in certain Lamb wave resonators with piston mode structures. With a border region that is too wide, the border region can function as a transducer itself, although transverse spurious modes can have increased suppression above the resonant frequency of such a Lamb wave resonator.

Aspects of this disclosure relate to a Lamb wave resonator that includes a piezoelectric layer having an engineered region and an active region. The piezoelectric layer can be less piezoelectric in the engineered region than in the active region. The piezoelectric layer has a lower effective piezoelectric coefficient in the engineered region than in the active region. The piezoelectric layer can be an AlN based piezoelectric layer. The engineered region can be in a border region of the Lamb wave resonator. Accordingly, the piezoelectric layer can be less piezoelectric in the border region of the Lamb wave resonator than in the active region. The engineered region can vertically overlap with end portions of IDT electrode fingers of an IDT electrode of the Lamb wave resonator. In some instances, the engineered region can also be in one or more of a gap region, a bus bar region, or another perimeter region around the active aperture of the Lamb wave resonator. The Lamb wave resonator can operate in a Sₒ mode or a S₁ mode. Such Lamb wave resonators can have type-1 dispersion and achieve a relatively large electromechanical coupling coefficient (kt²). In some other instances, the Lamb wave resonator can operate in a type-2 dispersion mode.

The Lamb wave resonator can have a border region width that is sufficient to suppress transverse modes. The engineered region of the piezoelectric layer can further suppress transverse modes. With the engineered region of the piezoelectric layer, a piston mode structure of the Lamb wave resonator can be arranged to further boost Q without generating significant spurious. For example, a hammer head structure can be wider to boost Q and the engineered region can suppress spurious associated with the hammer head.

For the type-1 modes of a Lamb wave resonator, by including a border region with a relatively slow velocity on the edge of the acoustic aperture, a propagating mode can have a zero or near zero transverse wave vector in the active aperture. The transverse wave vector is real in the border region and imaginary in the gap region. One embodiment of the border region includes using a larger metal coverage ratio electrode in the border region. This can be a hammer head shape in the border region in plan view. FIG. 1 illustrates an example of an IDT electrode of a Lamb wave resonator with such a border region.

FIG. 1 illustrates an IDT electrode 10 of a Lamb wave resonator and the corresponding velocity profile for the Lamb wave resonator having generally uniform piezoelectric layer. The IDT electrode 10 includes a first bus bar 12, first fingers extending from the first bus bar 12, a second bus bar 16, and second fingers extending from the second bus bar 16. The IDT electrode 10 can be implemented with any suitable number of fingers. A resonant frequency of a Lamb wave resonator can be based on the geometry of the IDT electrode 10.

Each of the first fingers of the IDT electrode 10 includes a body portion 24A, 24B extending from the first bus bar 12 in an active region and an end portion 25A, 25B in a border region opposite the first bus bar 12. The end portions 25A, 25B include wider metal than the body potions 24A, 24B of the first fingers. This can result in a slower velocity in a border region than in the active region. The end portions 25A, 25B shown in FIG. 1 can be referred to as hammer heads. Similarly, each of the second fingers includes a body portion 28A, 28B extending from the second bus bar 16 in the active region and an end portion 29A, 29B in a border region opposite the second bus bar 16. The end portions 29A, 29B include wider metal than the body potions 28A, 28B of the second fingers. This can result in a slower velocity in the border region than in the active region. The end portions 29A, 29B can be referred to as hammer heads.

As illustrated in FIG. 1, the first fingers are wider in a border region along a length wp than in the active region along length wₐ. The first fingers are also wider in the border region along the length wp than in a gap region along length w_{g} in the IDT electrode 10. Similarly, in the IDT electrode 10, the second fingers are wider in a border region along a length wp than in the active region along length wₐ. The second fingers are also wider in the border region along the length wp than in a gap region along length w_{g} in the IDT electrode 10. The fingers include respective end portions 25A, 25B, 29A, 29B in border regions. The end portions 25A, 25B, 29A, 29B have a hammer head shape in border regions in FIG. 1.

FIG. 1 also includes a velocity profile of a Lamb wave resonator that includes the IDT electrode 10 and a piezoelectric layer having generally uniform piezoelectric material. The Lamb wave resonator that includes IDT electrode 10 has a reduced velocity in border regions compared to the gap regions and the active region. The reduced velocity in the border region is caused by the end portions 25A, 25B, 29A, 29B of the IDT electrode 10. In a bus bar region that includes bus bar 12 or 16, the velocity is lower compared to the border region.

A piezoelectric layer of a Lamb wave resonator can be a thin film. The piezoelectric layer can be an aluminum nitride layer. Alternatively, the piezoelectric layer can be any other suitable piezoelectric layer. In certain instances, the piezoelectric layer can be a lithium niobate layer or a lithium tantalate layer. In some applications, the piezoelectric layer can be doped. For example, the piezoelectric layer can be an aluminum nitride layer doped with scandium in some applications.

Aspects of this disclosure relate to a Lamb wave resonator that includes the piezoelectric layer with an engineered region to enhance performance. The engineered region can be in a border region of the Lamb wave resonator. With a piston mode structure and an engineered region of the piezoelectric layer positioned vertically relative to the piston mode structure, transverse modes can be suppressed without a piston mode structure transducing. The engineered region of the piezoelectric layer can extend to a gap region to reduce leaky waves. The engineered region of the piezoelectric layer can extend to a bus bar region to reduce leaky waves by apodization of an IDT aperture. The engineered region of the piezoelectric layer can be applied to one or more selected regions of a Lamb wave resonator.

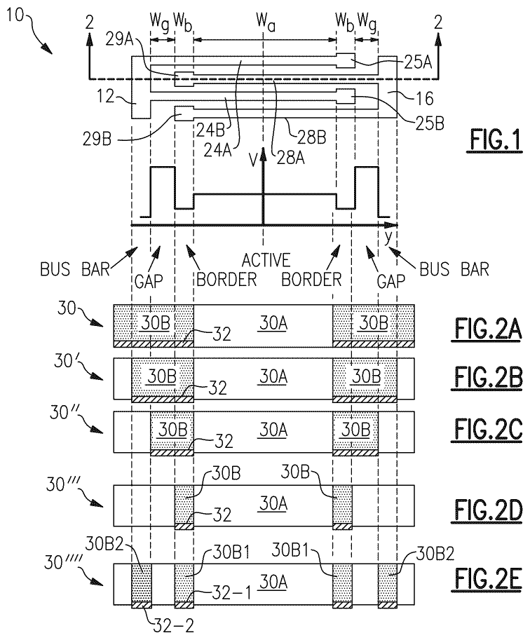

FIGS. 2A, 2B, 2C, 2D, and 2E are schematic cross-sectional diagrams of piezoelectric layers 30, 30′, 30″, 30′″, 30″″ of Lamb wave resonators each include an active region 30A and an engineered region 30B according to embodiments. The active region 30A can be referred to as the main acoustically active region. The active region 30A can be referred to as the main piezoelectric region. The engineered regions 30B are illustrated in the piezoelectric layers 30, 30′, 30″, 30′″, 30″″ of FIGS. 2A to 2E at positions that correspond to the regions of the IDT electrode 10 of FIG. 1. The engineered regions 30B can vertically overlap with corresponding parts of the IDT electrode 10.

The piezoelectric layers 30, 30′, 30″, 30′″, 30″″ can have a lower magnitude effective piezoelectric coefficient in the engineered region 30B than in the acoustically active region of 30A of a Lamb wave resonator. The piezoelectric coefficient can be a piezoelectric coupling coefficient (e₃₃), for example.

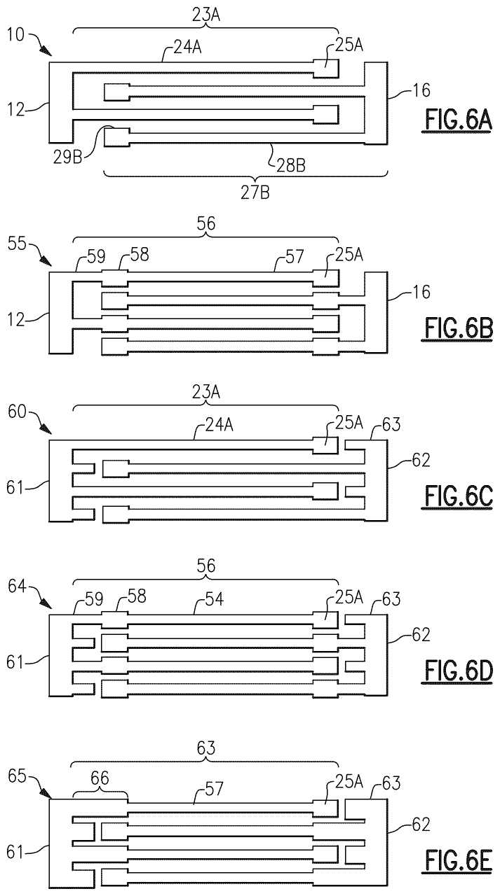

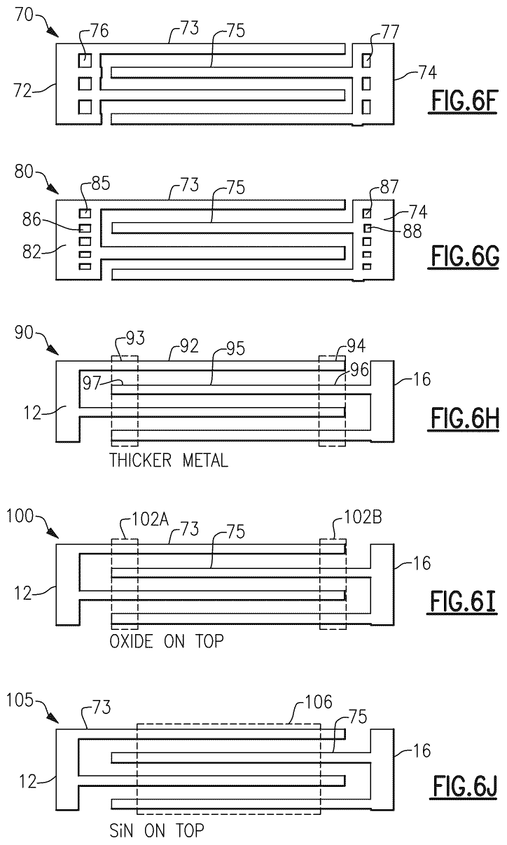

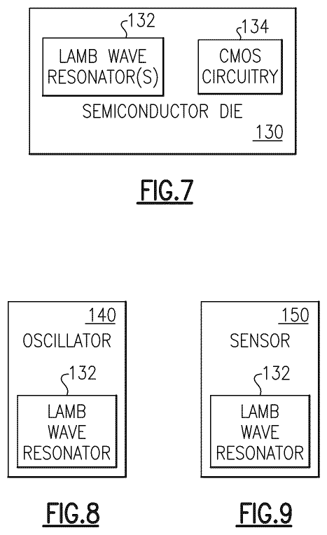

The engineered region 30B of piezoelectric layers 30, 30′, 30″, 30′″, 30″″ can be in a border region of a Lamb wave resonator on a border of the acoustic aperture of the Lamb wave resonator. The Lamb wave resonator can include a piston mode structure in the border region. The piston mode structure can include a hammer head as illustrated in FIG. 1, a piston mode structure of any of piston mode structures of FIGS. 6A to 6I, or any other suitable piston mode structure.

The engineered region 30B of the piezoelectric layer 30, 30′, 30″ can extend beyond the border region on a side opposite the active region. Examples of such piezoelectric layers 30, 30′, 30″ are illustrated in FIGS. 2A, 2B, and 2C. In certain applications, the engineered region 30B can overlap the border region only, for example, as shown in FIG. 2D. The engineered region 30B of a piezoelectric layer 30″″ can include a first region 30B1 in the border region and a second region 30B1 spaced apart from the first region 30B1, where the first region 30B1 is positioned between the second region 30B2 and the active region of the Lamb wave resonator. An example of such a piezoelectric layer 30″″ is illustrated in FIG. 2E. By reducing and/or eliminating the piezoelectric properties of the piezoelectric layer 30, 30′, 30″, 30′″, 30″″ in the border region of a Lamb wave resonator, there can be little or no resonance and/or acoustic activity associated with piston mode structure. The piezoelectric layer 30 can be engineered in a continuous region or two or more continuous regions.

The effective piezoelectric coefficient can be an aggregate piezoelectric coefficient for the entire engineered region 30B. The aggregate magnitude of the piezoelectric polarization vectors in the engineered region 30B should be less than the magnitude in the main piezoelectric region 30A. For example, the engineered region 30B of the piezoelectric layer 30 can have an effective piezoelectric coefficient magnitude that is less than 50% of the effective piezoelectric coefficient magnitude of the active region 30A of the piezoelectric layer 30. The lower magnitude effective piezoelectric coefficient in the engineered region 30B can be a result of the non-aligned nature of piezoelectric material crystal orientations within the engineered region 30B causing a lower aggregate magnitude of the piezoelectric polarization vectors.

The effective piezoelectric coefficient can be an effective piezoelectric coupling coefficient (e₃₃), for example. In certain applications, the magnitude of the effective piezoelectric coupling coefficient of the piezoelectric layer 30 in the engineered region 30B can be no more than 50% of the magnitude of the effective piezoelectric coupling coefficient of the piezoelectric layer 30 in the active region 30A. In some applications, the magnitude of the effective piezoelectric coupling coefficient of the piezoelectric layer 30 in the engineered region 30B can be no more than 20% of the magnitude of the effective piezoelectric coupling coefficient of the piezoelectric layer 30 in the active region 30A. In some applications, the magnitude of the effective piezoelectric coupling coefficient of the piezoelectric layer 30 in the engineered region 30B can be zero or close to zero. Even though the engineered region 30B may have little or no piezoelectricity, the engineered region 30B, can be considered parts of the piezoelectric layer 30, 30′, 30″, 30′″, or 30″″ of Lamb wave resonators of this disclosure. The piezoelectric layer 30 can also have a lower electromechanical coupling coefficient (kt²) in the engineered region 30B relative to the main acoustically active region 30A.

A seed layer 32 illustrated in FIGS. 2A to 2E can be positioned on an opposite side of the piezoelectric layer 30, 30′, 30″, 30′″, 30″″ as an interdigital transducer electrode. The seed layer 32 illustrated in FIGS. 2A to 2E can be positioned between an electrode of a Lamb wave resonator and the engineered region 30B of the piezoelectric layer 30, 30′, 30″, 30′″, 30″″. The seed layer 32 can cause the piezoelectric layer 30, 30′, 30″, 30′″, 30″″ to be engineered in the engineered region 30B during manufacture. The seed layer 32 can be formed of a material that has a relatively poor crystallinity or is crystalline with a relatively poor lattice match to the piezoelectric film applied over the seed layer 32. The piezoelectric layer 30, 30′, 30″, 30′″, 30″″ in the engineered region 30B over the seed layer 32 can have relatively poor bulk piezoelectric properties compared to the piezoelectric layer in the active region 30A. The seed layer 32 can be directly over an electrode of a Lamb wave resonator. The seed layer 32 can be a layer deposited by atomic deposition layer, for example. The seed layer 32 can include, but is not limited to, an oxide, a nitride, a carbide, a carbon structure (e.g., graphene or diamond), a boride, or any suitable combination thereof. In certain applications, the seed layer 32 can include one or more of aluminum oxide, silicon, silicon carbide, doped aluminum nitride, undoped aluminum nitride, aluminum, fused silica, boron nitride, diamond, silicon oxycarbide glass, silicon oxynitride glass, boron carbide, graphene, beryllium oxide, gallium nitride, indium nitride, silicon nitride, scandium nitride, or the like. In some embodiments, the seed layer 32 can have a thickness that is in a single digit nanometer range. In some embodiments, the seed layer 32 can have a thickness that is in a range from 1 nanometer to 100 nanometers. In some instances, the seed layer 32 can have a thickness that is in a range from 10 nanometers to 100 nanometers.

Modifying a relatively uniformly formed layer of piezoelectric material is another way to form an engineered region. In some applications, a uniform piezoelectric material can be deposited and then a region of the piezoelectric material can be modified to form an engineered region that is less piezoelectric than the active region 30A. For example, ions can be implanted to modify the structure and properties of the piezoelectric material by ion implantation to form the engineered region 30B.

FIG. 2A is schematic cross-sectional diagram of a piezoelectric layer 30 of a Lamb wave resonator according to an embodiment. The cross section corresponds to the piezoelectric layer below the IDT electrode 10 of FIG. 1 along the line 2-2 in an embodiment. The piezoelectric layer 30 includes an active region 30A and an engineered region 30B. The seed layer 32 is positioned below the engineered region 30B. The engineered region 30B is included on opposing sides of the active region 30A in plan view. The engineered region 30B can have the shape of two rectangular strips in plan view. In the piezoelectric layer 30 of FIG. 2A, the engineered region 30B is included in the border region, the gap region, and the bus bar region of a Lamb wave resonator. The border region of the Lamb wave resonator includes a piston mode structure. The gap region includes the gap between end portions of IDT electrode figures and an opposing bus bar. The bus bar region includes a bus bar. The engineered region 30B can extend beyond the bus bar away from the active region 30A. The engineered region 30B of FIG. 2A vertically overlaps with end portions 25A, 25B, 29A, 29B of IDT electrode fingers, gaps between IDT fingers and an opposing bus bar 12, 16, and a bus bar 12, 16. In certain applications, a Lamb wave resonator can include a piezoelectric layer 30 with an engineered region 30B that extends beyond the border region in a direction toward the active region.

FIG. 2B is schematic cross-sectional diagram of a piezoelectric layer 30′ of a Lamb wave resonator according to an embodiment. The cross section corresponds to the piezoelectric layer below the IDT electrode 10 of FIG. 1 along the line 2-2 in an embodiment. The piezoelectric layer 30′ includes an active region 30A and an engineered region 30B. The seed layer 32 is positioned below the engineered region 30B. The piezoelectric layer 30′ of FIG. 2B is like the piezoelectric layer 30 of FIG. 2A, except that the engineered region 30B of the piezoelectric layer 30 of FIG. 2A extends beyond the bus bar region away from the active region. The engineered region 30B of the piezoelectric layer 30′ of FIG. 2B has an edge that corresponds to an edge of the bus bar region.

FIG. 2C is schematic cross-sectional diagram of a piezoelectric layer 30″ of a Lamb wave resonator according to an embodiment. The cross section corresponds to the piezoelectric layer below the IDT electrode 10 of FIG. 1 along the line 2-2 in an embodiment. The piezoelectric layer 30″ includes an active region 30A and an engineered region 30B. The seed layer 32 is positioned below the engineered region 30B. The piezoelectric layer 30″ of FIG. 2C is like the piezoelectric layer 30′ of FIG. 2B, except that the engineered region 30B of the piezoelectric layer 30′ of FIG. 2B is included in the bus bar region. The engineered region 30B of the piezoelectric layer 30″ of FIG. 2C is included the border region and the gap region. The engineered region 30B of the piezoelectric layer 30″ of FIG. 2C is not included in the bus bar region.

FIG. 2D is schematic cross-sectional diagram of a piezoelectric layer 30′″ of a Lamb wave resonator according to an embodiment. The cross section corresponds to the piezoelectric layer below the IDT electrode 10 of FIG. 1 along the line 2-2 in an embodiment. The piezoelectric layer 30 includes an active region 30A and an engineered region 30B. The seed layer 32 is positioned below the engineered region 30B. The piezoelectric layer 30′″ of FIG. 2D is like the piezoelectric layer 30″ of FIG. 2C, except that the engineered region 30B of the piezoelectric layer 30″ of FIG. 2C is included in the gap region. The engineered region 30B of the piezoelectric layer 30′″ of FIG. 2D is included in the border region only. The engineered region 30B of the piezoelectric layer 30′″ of FIG. 2D is not included in the bus bar region or the gap region.

FIG. 2E is schematic cross-sectional diagram of a piezoelectric layer 30″″ of a Lamb wave resonator according to an embodiment. The cross section corresponds to the piezoelectric layer below the IDT electrode 10 of FIG. 1 along the line 2-2 in an embodiment. The piezoelectric layer 30″″ includes an active region 30A and an engineered region 30B. The engineered region 30B includes a first part 30B1 and a second part 30B2. The seed layer 32 includes a first part 32-1 and a second part 32-2 positioned below respective parts 30B1 and 30B2 of the engineered region 30B. The piezoelectric layer 30″″ of FIG. 2E is like the piezoelectric layer 30′ of FIG. 2B, except that the engineered region 30B of the piezoelectric layer 30′ of FIG. 2B is included in the gap region. The engineered region 30B of the piezoelectric layer 30″″ of FIG. 2E is included the border region and the bus bar region. The engineered region 30B of the piezoelectric layer 30″″ of FIG. 2E is not included in the gap region. FIG. 2E illustrates that an engineered region 30B can include two or more continuous regions that are spaced apart from each other.

FIG. 3 is a cross-sectional side view of a Lamb wave resonator 40 according to an embodiment. The Lamb wave resonator includes an IDT electrode 10, a piezoelectric layer 30, an electrode 42, an acoustic reflector 44, and a substrate 46. The cross-sectional view of FIG. 3 corresponds to the IDT electrode 10 of FIG. 1 along the line 2-2 in an embodiment. In the Lamb wave resonator 40, the piezoelectric layer 30 corresponds to the piezoelectric layer 30 of FIG. 2A. Any suitable principles and advantages of the piezoelectric layers disclosed herein can be implemented in accordance with any suitable principles and advantages of the Lamb wave resonator 40. For example, although the Lamb wave resonator 40 corresponds to the piezoelectric layer 30 of FIG. 2A, a similar Lamb wave resonator can be implemented with a piezoelectric of any of FIGS. 2B to 2E.

As illustrated in FIG. 3, the engineered region 30B of the piezoelectric layer 30 vertically overlaps with the bus bar 12, a gap between the bus bar 12 and an IDT electrode finger, and an end portion 25A of the IDT electrode finger on a side of the cross section of the Lamb wave resonator 40. The engineered region 30B is also included on an opposite side of the Lamb wave resonator 40 in the cross sectional view shown in FIG. 3. The engineered region 30B is over the acoustic reflector 42 in the Lamb wave resonator 40.

The electrode 42 is on an opposite side of the piezoelectric layer 30 than the IDT electrode 10. The electrode 42 can be continuous in an acoustic aperture of the Lamb wave resonator 40. The electrode 42 can be continuous and cover an entire area of the IDT electrode 10 including gap regions and spacings between IDT electrode fingers. The electrode 42 can be grounded in certain instances. In some other instances, the electrode 42 can be floating. The electrode 42 can have a shape corresponding to an electrode of a BAW resonator.

The seed layer 32 is on an opposite side of the piezoelectric layer 30 than the IDT electrode 10. In the illustrated Lamb wave resonator 40, the seed layer 32 is positioned between the electrode 42 and the engineered region 30B of the piezoelectric layer 30. The Lamb wave resonator 40 is free from the seed layer 32 between the electrode 42 and the active region 30A of the piezoelectric layer 30.

The acoustic reflector 44 of the Lamb wave resonator 40 illustrated in FIG. 3 is an air cavity. In some other applications, an acoustic reflector can be a solid acoustic mirror including acoustic Bragg reflectors instead of an air cavity. A solid acoustic mirror can be implemented in place of an air cavity in a Lamb wave resonator in accordance with any suitable principles and advantages disclosed herein. The acoustic reflector 44 is positioned between the electrode 42 and the substrate 46 in the Lamb wave resonator 40.

The substrate 46 can be a semiconductor substrate. For example, the substrate 46 can be a silicon substrate in certain applications. Any other suitable substrate 46 can be implemented to provide structural support for the Lamb wave resonator 40.

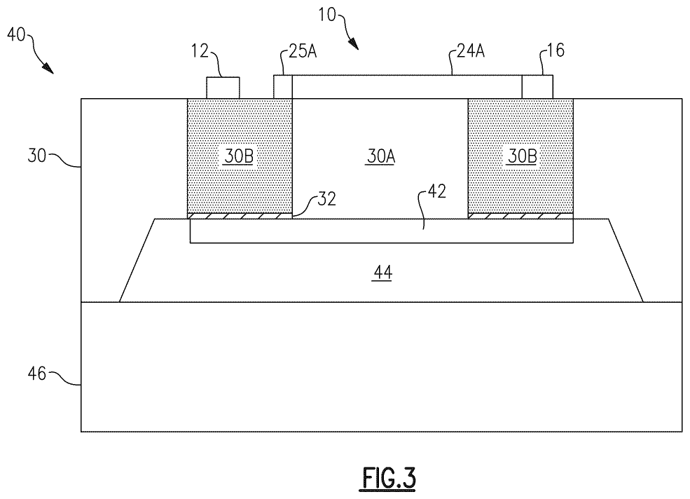

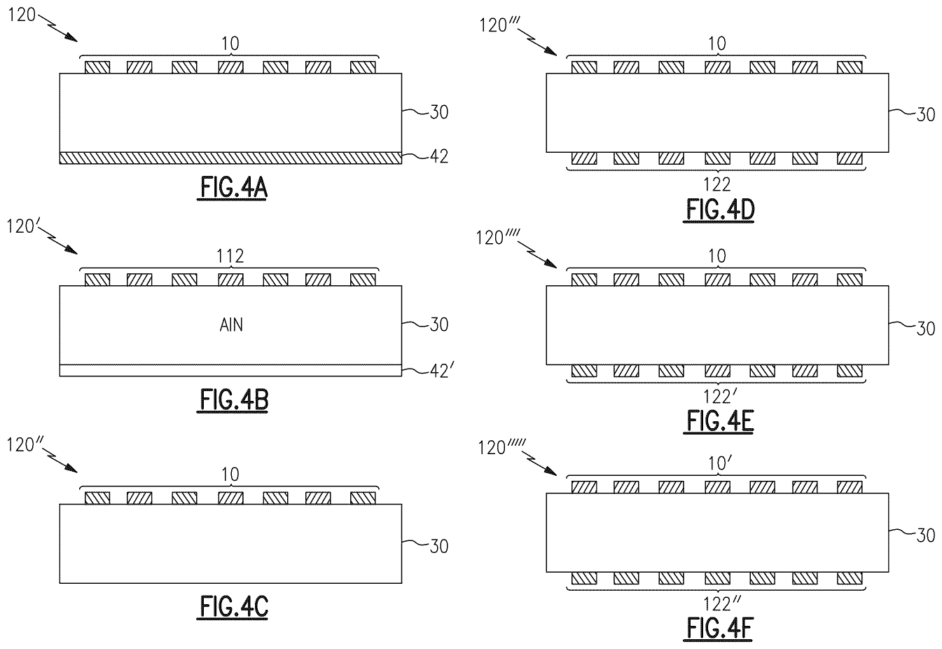

Lamb wave resonators can include an IDT electrode with free edges. Suspended free edges of a piezoelectric layer can provide acoustic wave reflection to form a resonant cavity in such resonators. FIGS. 4A to 4F are diagrams of cross sections of Lamb wave resonators with free edges. The cross-sectional diagrams of FIGS. 4A to 4F are along a line through an active region of the Lamb wave resonator. The cross-sectional views of FIGS. 4A to 4F can be generally perpendicular to a cross-sectional view along an IDT electrode such as the cross-sectional diagram of FIG. 3. The Lamb wave resonators 4A to 4F can include an engineered region in accordance with any suitable principles and advantages disclosed herein. A Lamb wave resonator with a piezoelectric layer having an engineered region can be implemented with any suitable principles and advantages of any of the Lamb wave resonators of FIGS. 4A to 4F. Although the Lamb wave resonators of FIGS. 4A to 4F are free-standing resonators, any suitable principles and advantages of these Lamb wave resonators can be applied to other Lamb wave resonators.

FIG. 4A illustrates a portion of a Lamb wave resonator 120 that includes an IDT electrode 10, piezoelectric layer 30, and electrode 42. The IDT electrode 10 is on the piezoelectric layer 30. In the illustrated cross section, alternate ground and signal electrodes are included in the IDT electrode 10. The piezoelectric layer 30 has free edges on opposing sides of the IDT electrode 10. The electrode 42 and the IDT electrode 10 are on opposite sides of the piezoelectric layer 30. The piezoelectric layer 30 can be aluminum nitride, for example. The piezoelectric layer 30 includes an engineered region that can be substantially parallel to the cross-section illustrated in FIG. 4A. The electrode 42 can be grounded.

FIG. 4B illustrates a portion of a Lamb wave resonator 120′. The Lamb wave resonator 120′ is like the Lamb wave resonator 120 of FIG. 4A except that the Lamb wave resonator 120′ includes a floating electrode 42′.

FIG. 4C illustrates a portion of a Lamb wave resonator 120″ without an electrode on a side of the piezoelectric layer 30 that opposes the IDT electrode 10.

FIG. 4D illustrates a portion of a Lamb wave resonator 120′″ that includes an IDT electrode 122 on a second side of the piezoelectric layer 30 that is opposite to a first side on which the IDT electrode 10 is positioned. The signal and ground electrodes are offset relative to each other for the IDT electrodes 10 and 122.

FIG. 4E illustrates a portion of a Lamb wave resonator 120″″ that includes an IDT electrode 122′ on a second side of the piezoelectric layer 30 that is opposite to a first side on which the IDT electrode 10 is positioned. The signal and ground electrodes are aligned with each other for the IDT electrodes 10 and 122′.

FIG. 4F illustrates a portion of a Lamb wave resonator 120′″″ that includes an IDT electrode 122″ on a second side of the piezoelectric layer 30 that is opposite to a first side on which the IDT electrode 10′ is positioned. In the illustrated cross section, the IDT electrode 10′ includes only signal electrodes and the IDT electrode 122″ includes only ground electrodes.

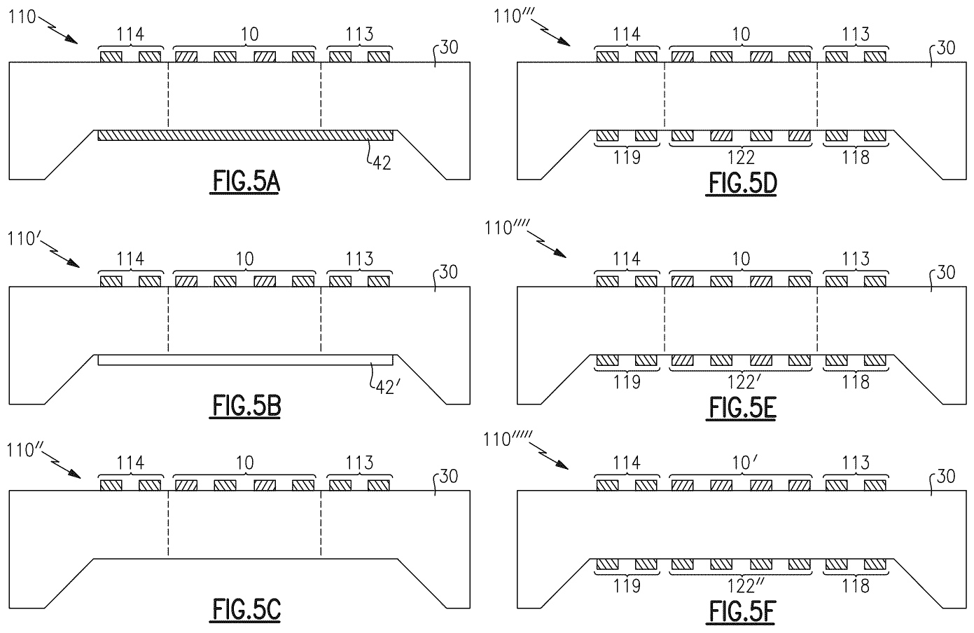

Lamb wave resonators can include an IDT electrode on a piezoelectric layer and reflective gratings positioned on the piezoelectric layer on opposing sides of the IDT electrode. The reflective gratings can reflect acoustic waves induced by the IDT electrode. The reflective gratings can include a periodic pattern of metal on a piezoelectric layer. FIGS. 5A to 5F are diagrams of cross sections of Lamb wave resonators with gratings. The cross-sectional diagrams of FIGS. 5A to 5F are along a line through an active region of the Lamb wave resonator. The cross-sectional diagrams of FIGS. 5A to 5F can be generally perpendicular to a cross-sectional view along an IDT electrode, such as the cross-sectional diagram of FIG. 3. The Lamb wave resonators 5A to 5F can include an engineered region in accordance with any suitable principles and advantages disclosed herein. Although the Lamb wave resonators of FIGS. 5A to 5F are free-standing resonators, any suitable principles and advantages of these Lamb wave resonators can be applied to any other suitable Lamb wave resonators.

FIG. 5A illustrates a portion of a Lamb wave resonator 110 that includes an IDT electrode 10, gratings 113 and 114, a piezoelectric layer 30, an electrode 42, and an acoustic reflector 44 (e.g., an air cavity as illustrated). The IDT electrode 10 is on the piezoelectric layer 30. In the illustrated cross section, alternate ground and signal metals are included in the IDT electrodes. Gratings 113 and 114 are on the piezoelectric layer 30 and positioned on opposing sides of the IDT electrodes 10. The illustrated gratings 113 and 114 are shown as being connected to ground. Alternatively, one or more of the gratings can be signaled and/or floating. The electrode 42 and the IDT electrode 10 are on opposite sides of the piezoelectric layer 30. The piezoelectric layer 30 can be AlN, for example. In some instances, the piezoelectric layer 30 is an AlN layer doped with scandium (Sc). The piezoelectric layer 30 can be an aluminum scandium nitride (AlScN) layer. The piezoelectric layer 30 includes an engineered region that can be substantially parallel to the cross-section illustrated in FIG. 5A. The electrode 42 can be grounded.

FIG. 5B illustrates a portion of a Lamb wave resonator 110′. The Lamb wave resonator 110′ is like the Lamb wave resonator 110 of FIG. 5A except that the Lamb wave resonator 110′ includes a floating electrode 42′.

FIG. 5C illustrates a portion of a Lamb wave resonator 110″ without an electrode on a side of the piezoelectric layer 30 that opposes the IDT electrode 10.

FIG. 5D illustrates a portion of a Lamb wave resonator 110′″ that includes an IDT electrode 122 and gratings 118 and 119 on a second side of the piezoelectric layer 30 that is opposite to a first side on which the IDT electrode 10 and gratings 113 and 114 are positioned. The signal and ground electrodes are offset relative to each other for the IDT electrodes 10 and 122.

FIG. 5E illustrates a portion of a Lamb wave resonator 110″″ that includes an IDT electrode 122′ and gratings 118 and 119 on a second side of the piezoelectric layer 30 that is opposite to a first side on which the IDT electrode 10 and gratings 113 and 114 are positioned. The signal and ground electrodes are aligned with each other for the IDT electrodes 10 and 122′.

FIG. 5F illustrates a portion of a Lamb wave resonator 110′″″ that includes an IDT electrode 122″ and gratings 118 and 119 on a second side of the piezoelectric layer 30 that is opposite to a first side on which the IDT electrode 10′ and gratings 113 and 114 are positioned. In the illustrated cross section, the IDT electrode 10′ includes only signal electrodes and the IDT electrode 122″ includes only ground electrodes.

Piston mode structures of Lamb wave resonators can be implemented in a variety of ways. For example in FIG. 1, a hammer head structure of the IDT electrode 10 is a piston mode structure. In certain applications, a metal layout of an IDT electrode of a Lamb wave resonator can contribute to a velocity in a border region having a lower magnitude than a velocity in an active region. For instance, an end portion of an interdigital transducer electrode finger can have wider metal than the rest of the finger. As another example, a layer over an interdigital transducer electrode can contribute to a velocity in a border region having a lower magnitude than a velocity in an active region. Such a layer can be over the active region to increase the magnitude of the velocity in the active region relative to the border region. Alternatively or additionally, a layer over the border region can reduce the velocity of the border region relative to the active region.

Example embodiments of IDT electrodes with piston mode structures will be discussed with reference to FIGS. 6A to 6J. In the Lamb wave resonators of any of FIGS. 6A to 6J, an IDT electrode can be on aluminum nitride piezoelectric layer. Any suitable principles and advantages of these embodiments can be combined with each other. Any suitable principles and advantages of these embodiments of the can be implemented in a Lamb wave resonator that includes a piezoelectric layer with an engineered region in accordance with any suitable principles and advantages disclosed herein. For example, a Lamb wave resonator with an IDT electrode of any of FIGS. 6A to 6J can include a piezoelectric layer that includes an engineered region in at least a border region.

FIG. 6A illustrates an IDT electrode 10 of a Lamb wave resonator according to an embodiment. The IDT electrode 10 includes fingers having hammer head shaped end portions. The IDT electrode 10 includes bus bars 12 and 16 and a plurality of fingers extending from the bus bars 12 and 16. As illustrated, each of the fingers of the IDT electrode 10 are substantially the same. Finger 23A will be discussed as an example. Finger 23A has a body portion 24A that extends from bus bar 12 and an end portion 25A. The end portion 25A is adjacent to and spaced apart from the bus bar 16. The end portion 25A is wider that the rest of the finger 23A. The end portion 25A is hammer head shaped in plan view. The end portions of the fingers of the IDT electrode 10 are piston mode structures that can suppress transverse spurious modes. An engineered region of a piezoelectric layer of the Lamb wave resonator can vertically overlap with the end portions on each side of the IDT electrode 10.

FIG. 6B illustrates an IDT electrode 55 of a Lamb wave resonator according to another embodiment. The IDT electrode 55 has with thicker metal portions for both border regions of each finger. The IDT electrode 55 is like the IDT electrode 10 of FIG. 6A except that the fingers of the IDT electrode 55 are wider adjacent to both bus bars 12 and 16. Finger 56 will be discussed as an example. Finger 56 has a bus bar connection portion 59 that extends from bus bar 12, a widened portion 58, a body portion 57, and an end portion 25A. Both the end portion 25A and the widened portion 58 are wider than the other portions of the finger 56. The widened portion 58 and the end portion 25A of the finger 56 are included in border regions on opposing sides of the active region of the Lamb wave resonator that include the IDT electrode 55. The end portions and widened portions of the fingers of the IDT electrode 55 can be piston mode structures. An engineered region of a piezoelectric layer of the Lamb wave resonator can vertically overlap with the end portions and widened portions of the IDT electrode 55.

FIG. 6C illustrates an IDT electrode 60 of a Lamb wave resonator according to another embodiment. The IDT electrode 60 includes fingers having hammer head shaped end portions and bus bars having extension portions adjacent to the end portions of the fingers. The IDT electrode 60 is like the IDT electrode 10 of FIG. 6A except that the bus bars of the IDT electrode 60 have extension portions adjacent to end portions of fingers. Bus bars 61 and 62 each include extension portions, such as extension portion 63, adjacent to and spaced apart from end portions of fingers of the IDT electrode 60. The extension portions of the bus bars 61 and 62 can increase the metal coverage ratio around the border regions relative to the active region of the Lamb wave resonator. An engineered region of a piezoelectric layer of the Lamb wave resonator can vertically overlap with the end portions of the fingers and extension portions of the bus bars of the IDT electrode 60.

FIG. 6D illustrates an IDT electrode 64 of a Lamb wave resonator according to another embodiment. The IDT electrode 64 has thicker end portions on border regions of each finger and bus bars having extension portions adjacent to end portions of the fingers. The IDT electrode 64 includes features of the IDT electrode 60 of FIG. 6C and features of the IDT electrode 55 of FIG. 6B. An engineered region of a piezoelectric layer of the Lamb wave resonator can vertically overlap with end portions of the fingers, widened portions of the fingers, and extension portions of the bus bars of the IDT electrode 64.

FIG. 6E illustrates an IDT electrode 65 of a Lamb wave resonator according to another embodiment. The IDT electrode 65 includes fingers having thicker end portions and thicker regions extending from a bas bar toward an active region of the Lamb wave resonator. The IDT electrode 65 is similar to the IDT electrode 60 of FIG. 6C except the fingers of IDT electrode 65 include a widened portion extending from bus bars. As shown in FIG. 6E, finger 68 of the IDT electrode 65 includes widened portion 66 extending from the bus bar 61 to body portion 57. The finger 68 also includes end portion 25A. An engineered region of a piezoelectric layer of the Lamb wave resonator can vertically overlap with widened portions 66 extending from the bus bar.

FIG. 6F illustrates an IDT electrode 70 of a Lamb wave resonator according to another embodiment. The IDT electrode 70 includes with bus bars 72 and 74 and fingers 73 and 75 extending from the respective bus bars. The bus bars 72 and 74 have holes 76 and 77, respectively. The holes 76 and 77 are adjacent to ends of the fingers 75 and 73, respectively. The holes can reduce a metal coverage ratio adjacent to border regions. An engineered region of a piezoelectric layer of the Lamb wave resonator can vertically overlap with the border regions and/or the holes in the bus bars.

FIG. 6G illustrates an IDT electrode 80 of a Lamb wave resonator according to another embodiment. The IDT electrode 80 is like the IDT electrode 70 of FIG. 6F except that the bus bars have different holes. As illustrated in FIG. 6G, the IDT electrode 80 includes bus bars 82 and 84 having holes 86 and 88, respectively. An engineered region of a piezoelectric layer of the Lamb wave resonator can vertically overlap with the border regions and/or the holes in the bus bars.

FIG. 6H illustrates an IDT electrode 90 of a Lamb wave resonator according to another embodiment. The IDT electrode 90 includes bus bars 12 and 16 and fingers 92 and 95 extending from the bus bars 12 and 16, respectively. The finger 92 has thicker metal in border region portions 93 and 94 than the rest of the finger 92. Similarly, the finger 94 has thicker metal in border region portions 96 and 97 than in other portions of the finger 94. Thicker metal can provide similar functionality as wider metal. An engineered region of a piezoelectric layer of the Lamb wave resonator can vertically overlap with the border regions.

FIG. 6I illustrates an IDT electrode 100 of a Lamb wave resonator according to an embodiment. The IDT electrode 100 has an oxide over border regions 102A and 102B of the IDT electrode 100. The oxide can cause a magnitude of the velocity in the border regions to be less than the velocity in the active region of the Lamb wave resonator. Any other suitable material can be included over border regions 102A and 102B to reduce the magnitude of the velocity of the border regions relative to the active region. An engineered region of a piezoelectric layer of the Lamb wave resonator can vertically overlap with the border regions.

FIG. 6J illustrates an IDT electrode 105 of a Lamb wave resonator according to another embodiment. The IDT electrode 105 has silicon nitride over active region 106 of the IDT electrode 105. The silicon nitride can cause a magnitude of the velocity in the active region to be greater than the velocity in a border active region of the Lamb wave resonator. Any other suitable material can be included over the active region 106 to increase the magnitude of the velocity of the active region relative to the border regions. An engineered region of a piezoelectric layer of the Lamb wave resonator can vertically overlap with the border regions and/or the holes in the bus bars.

As discussed above, aluminum nitride Lamb wave resonators can be compatible with CMOS process technology. Accordingly, CMOS circuitry and an aluminum nitride Lamb wave resonator can be implemented on a common semiconductor die.

FIG. 7 is a schematic block diagram of a semiconductor die 130 that includes a Lamb wave resonator 132 according to an embodiment and CMOS circuitry 134. Advantageously, the Lamb wave resonator 132 can include an aluminum nitride based piezoelectric layer that can be integrated with the CMOS circuitry 134 on a common semiconductor die 130. The Lamb wave resonator 132 can include a piezoelectric layer with an engineered region in accordance with any suitable principles and advantages disclosed herein.

The Lamb wave resonators disclosed herein can be implemented in various applications. Lamb wave resonators disclosed herein can be implemented in a variety of applications. Applications of these Lamb wave resonators include, but are not limited to, a Lamb wave resonator for filter that filters an electrical signal, an oscillator such as an oscillator for a clock generator, a sensor (e.g., a gas sensor, a particle sensor, a mass sensor, a pressure or touch sensor, etc.), a delay line such as a delay line for radar and/or instrumentation applications, an actuator, a microphone, and a speaker. Filters that include Lamb wave resonators can be implemented in a variety of applications including, but not limited to, mobile phones, base stations, repeaters, relays, wireless communication infrastructure, access points, customer premises equipment (CPE), and distributed antenna systems. Oscillators that include a Lamb wave resonator can replace crystal oscillators in a variety of applications, such as but not limited to electronic timing products. Example applications will now be discussed.

FIG. 8 illustrates that an oscillator 140 can include a Lamb wave resonator 132 according to an embodiment. The oscillator 140 can be any oscillator that could benefit from a Lamb wave resonator. For example, the oscillator 140 can be included in a radio frequency front end. The oscillator 140 can be implemented in place of another oscillator, such as a quartz oscillator, in a variety of applications. The oscillator 140 can be implemented in a part with another oscillator, such as a quartz oscillator, in some applications. The oscillator 140 can provide a frequency reference. The oscillator 140 can generate a local oscillator for up converting and/or a down converting a signal.

FIG. 9 illustrates that a sensor 150 can include a Lamb wave resonator 132 according to an embodiment. The sensor 150 can be any sensor that could benefit from a Lamb wave resonator. For example, the sensor 150 can be arranged to sense pressure, to sense temperature, or to sense any other suitable parameter. In some instances, the sensor 150 can be configured for in liquid sensing applications.

Lamb wave resonators disclosed herein can be implemented in a variety of filters. Such filters can be arranged to filter a radio frequency signal. Lamb wave resonators disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, Lamb wave resonators disclosed herein can be implemented in filters with one or more other types of resonators and/or with passive impedance elements, such as one or more inductors and/or one or more capacitors. An example filter topology will be discussed with reference to FIG. 4A.

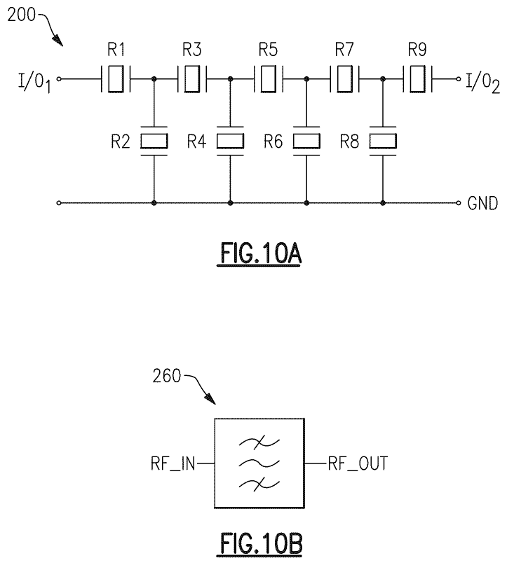

FIG. 10A is a schematic diagram of a ladder filter 200 that includes an acoustic wave resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, the first input/output port I/O₁ can be a receive port and the second input/output port I/O₂ can be an antenna port. One or more of the acoustic wave resonators of the ladder filter 200 can include a Lamb wave resonator in accordance with any suitable principles and advantages disclosed herein. All acoustic resonators of the ladder filter 200 can include a Lamb wave resonator in accordance with any suitable principles and advantages disclosed herein in certain instances.

A filter that includes a Lamb wave resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band. A filter that includes a BAW resonator in accordance with any suitable principles and advantages disclosed herein can be arranged to filter a radio frequency signal in any other suitable operating band, such as a WiFi operating band, a Global Positioning System (GPS) operating band, a Bluetooth operating band, a ZigBee operating band, a WiMax operating band, etc.

The Lamb wave resonators disclosed herein can be advantageous for implementing Lamb wave resonators with relatively high Qp and relatively low spur intensity. Lamb wave resonators disclosed herein can have significantly better performance than a variety of other Lamb wave resonators. This can be advantageous in meeting demanding specifications for acoustic wave filters, such as performance specifications for certain 5G applications.

FIG. 10B is schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a Lamb wave resonator according to an embodiment.

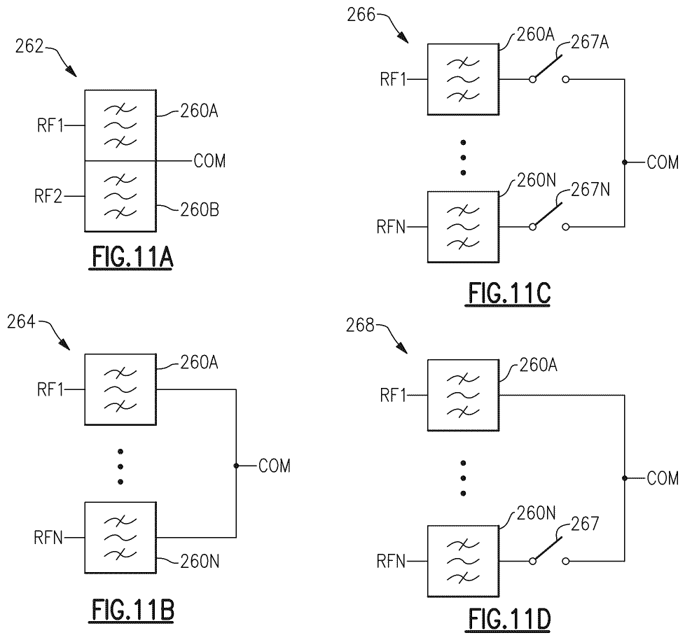

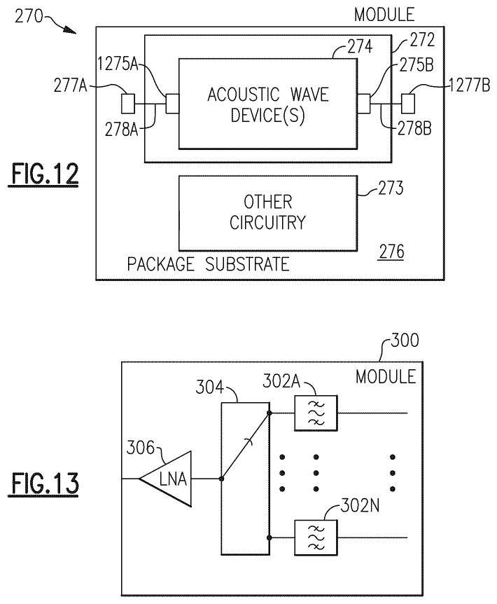

The Lamb wave resonators disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 11A to 11D. Any suitable principles and advantages of these multiplexers can be implemented together with each other.

FIG. 11A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a Lamb wave resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a Lamb wave resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 11B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a Lamb wave resonator in accordance with any suitable principles and advantages disclosed herein. The other filter(s) of the multiplexer 264 can include one or more acoustic wave filters, one or more acoustic wave filters that include a Lamb wave resonator in accordance with any suitable principles and advantages disclosed herein, one or more LC filters, one or more hybrid acoustic wave LC filters, the like, or any suitable combination thereof.

FIG. 11C is a schematic diagram of a multiplexer 266 that includes an acoustic wave filter according to an embodiment. The multiplexer 266 is like the multiplexer 264 of FIG. 11B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 11D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

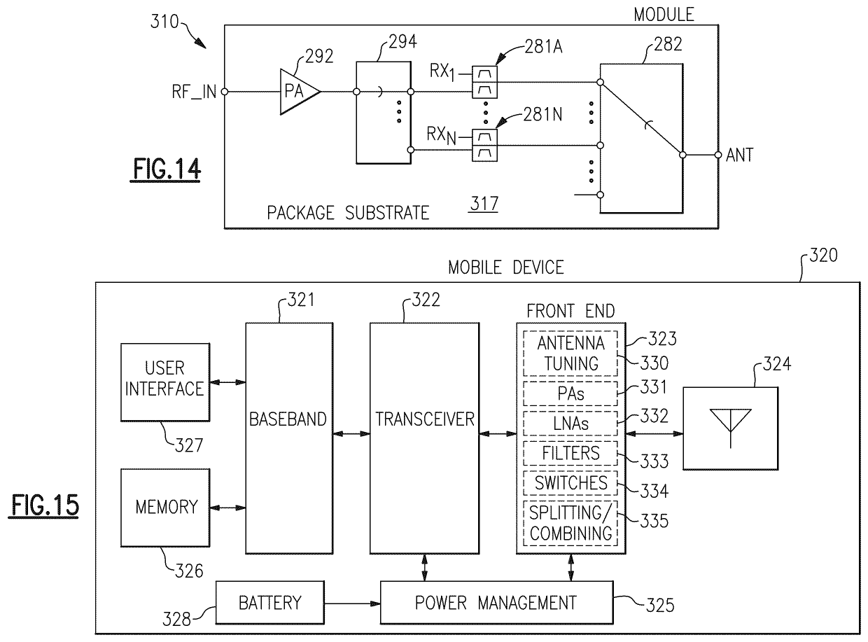

Acoustic wave devices disclosed herein can be implemented in a variety of packaged modules. Some example packaged modules will now be disclosed in which any suitable principles and advantages of the Lamb wave resonators disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 12, 14, and 14 are schematic block diagrams of illustrative packaged modules according to certain embodiments. Any suitable combination of features of these packaged modules can be implemented with each other.

FIG. 12 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be Lamb wave resonators in certain applications.

The acoustic wave component 272 shown in FIG. 12 includes one or more acoustic wave devices 274 and terminals 275A and 275B. The one or more acoustic wave devices 274 include one or more Lamb wave resonators implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 12. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

FIG. 13 is a schematic block diagram of a module 300 that includes filters 302A to 302N, a radio frequency switch 304, and a low noise amplifier 306 according to an embodiment. One or more filters of the filters 302A to 302N can include any suitable number of Lamb wave resonators in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

FIG. 14 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 8 and/or additional elements. The radio frequency module 310 may include any one of the acoustic wave filters that include at least one Lamb wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a Lamb wave resonator in accordance with any suitable principles and advantages disclosed herein. Similarly, one or more of the receive filters can include a Lamb wave resonator in accordance with any suitable principles and advantages disclosed herein. Although FIG. 8 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

The Lamb wave resonators disclosed herein can be implemented in wireless communication devices. FIG. 15 is a schematic block diagram of a wireless communication device 320 that includes a Lamb wave resonator according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 15 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAS) 331, low noise amplifiers (LNAs) 332, filters 333, switches 334, and signal splitting/combining circuitry 335. However, other implementations are possible. The filters 333 can include one or more acoustic wave filters that include any suitable number of Lamb wave resonators in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 15, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 15, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHZ, in FR1, in a frequency range from about 2 GHz to 10 GHz, in a frequency range from about 2 GHz to 15 GHZ, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A Lamb wave resonator having an active region and a border region, the Lamb wave resonator comprising:
a piezoelectric layer having an effective piezoelectric coefficient in the border region with a lower magnitude than an effective piezoelectric coefficient in the active region; and
an interdigital transducer electrode including a plurality of interdigital transducer electrode fingers having respective end portions in the border region, the Lamb wave resonator configured to generate a Lamb wave.

2. The Lamb wave resonator of claim 1 further comprising an electrode on an opposite side of the piezoelectric layer than the interdigital transducer electrode.

3. The Lamb wave resonator of claim 2 further comprising a seed layer positioned between the electrode and the piezoelectric layer in the border region, the Lamb wave resonator being free from the seed layer in the active region.

4. The Lamb wave resonator of claim 2 further comprising an air cavity, the electrode positioned between at least a portion of the piezoelectric layer and the air cavity.

5. The Lamb wave resonator of claim 1 wherein the interdigital transducer electrode includes a piston mode structure in the border region.

6. The Lamb wave resonator of claim 1 wherein the end portions of the interdigital transducer electrode are hammer head shaped in plan view.

7. The Lamb wave resonator of claim 1 wherein the Lamb wave resonator has a gap region and a bus bar region, the gap region being between the border region and the bus bar region, and the piezoelectric layer has an effective piezoelectric coefficient in the gap region with a lower magnitude than the effective piezoelectric coefficient in the active region.

8. The Lamb wave resonator of claim 1 wherein the Lamb wave resonator has a bus bar region, the interdigital transducer electrode includes a bus bar in the bus bar region, and the piezoelectric layer has an effective piezoelectric coefficient in the bus bar region with a lower magnitude than the effective piezoelectric coefficient in the active region.

9. The Lamb wave resonator of claim 1 wherein the Lamb wave resonator is configured to operate in a lowest order symmetric (S₀) mode.

10. The Lamb wave resonator of claim 1 wherein the Lamb wave resonator is configured to operate in a first order symmetric (S₁) mode.

11. The Lamb wave resonator of claim 1 wherein the Lamb wave resonator has free edges.

12. The Lamb wave resonator of claim 1 wherein the effective piezoelectric coefficient of the piezoelectric layer in the border region has a magnitude that is less than 50% of a magnitude of the effective piezoelectric coefficient of the piezoelectric layer in the active region.

13. A Lamb wave resonator comprising:
an interdigital transducer electrode including interdigital transducer electrode fingers having respective end portions; and
a piezoelectric layer having an active region and an engineered region, the engineered region overlapping with the end portions of the interdigital transducer electrode fingers, the Lamb wave resonator configured to generate a Lamb wave.

14. The Lamb wave resonator of claim 13 further comprising an electrode on an opposite side of the piezoelectric layer than the interdigital transducer electrode.

15. The Lamb wave resonator of claim 14 further comprising a seed layer positioned between the electrode and the engineered region of the piezoelectric layer, the Lamb wave resonator being free from the seed layer between the electrode and the active region of the piezoelectric layer.

16. The Lamb wave resonator of claim 14 further comprising an air cavity, the electrode positioned between at least a portion of the piezoelectric layer and the air cavity.

17. The Lamb wave resonator of claim 13 wherein the engineered region extends beyond the end portions in a direction away from the active region.

18. The Lamb wave resonator of claim 13 wherein the interdigital transducer electrode includes a piston mode structure that overlaps with the engineered region.

19. The Lamb wave resonator of claim 13 wherein the Lamb wave resonator has free edges.

20. An acoustic wave filter for filtering a radio frequency signal, the acoustic wave filter comprising:
a Lamb wave resonator having a border region and an active region, the Lamb wave resonator including an interdigital transducer electrode and an piezoelectric layer, the piezoelectric layer having an effective piezoelectric coefficient in the border region with a lower magnitude than an effective piezoelectric coefficient in the active region, and the interdigital transducer electrode including a plurality of interdigital transducer electrode fingers having respective end portions in the border region; and
a plurality of additional acoustic wave resonators, the Lamb wave resonator and the plurality of additional acoustic wave resonators configured to filter the radio frequency signal.
